(19) United States
(12) Patent Application Publication
(10) Pub. No.: US 2014/0202851 A1
(43) Pub. Date: Jul. 24, 2014

(54) BORON-DOPED ZINC OXIDE SPUTTERING TARGET AND ITS APPLICATION

(71) Applicant: SOLAR APPLIED MATERIALS TECHNOLOGY CORP., (US)

(72) Inventors: Yen-Ming LIU, Tainan (TW); Chih-Yung CHANG, Tainan (TW); Hui-Ying SHIU, Tainan (TW)

(73) Assignee: SOLAR APPLIED MATERIALS TECHNOLOGY CORP., Tainan (TW)

(21) Appl. No.: 13/746,410

(22) Filed: Jan. 22, 2013

(51) Int. Cl. C23C 14/08

(52) U.S. Cl. CPC C23C 14/086
USPC 204/298.13

(57) ABSTRACT

A boron-doped zinc oxide sputtering target, BZO sputtering target, is provided to deposit a BZO film by direct current sputtering. The BZO sputtering target has an amount of B/(B+Zn) ranging from 1.15 atomic % to 6.74 atomic % and a second phase ranging from 2% to 25% relative to a total area of the matrix phase and the second phase. Accordingly, a BZO film having a transmittance higher than 80% within a wavelength from 400 nanometers to 1100 nanometers and a resistivity less than 1×10⁻² Ω-cm can be prepared by DC sputtering the BZO sputtering target.

### BACKGROUND OF THE INVENTION

1. Field of the Invention

The present invention relates to a boron-doped zinc oxide sputtering target, and more particularly to a boron-doped zinc oxide sputtering target applicable for direct current sputtering (DC sputtering). In addition, the present invention also relates to a method of producing a boron-doped zinc oxide thin film by DC sputtering and a produced boron-doped zinc oxide thin film.

2. Description of the Prior Arts

Transparent conducting oxide (TCO), with a transmittance higher than 80% in the near infrared region and a sheet resistivity less than 10 Ω/square, has been widely applied to various photoelectric products, such as solar cells, flat panel displays and photo emitting diodes, as a suitable material for transparent conducting electrodes.

Conventional transparent conducting oxide includes tin-doped indium oxide (ITO) or zinc oxide. However, ITO is gradually replaced by other TCOs due to the shortage and high cost of indium and reduction by hydrogen plasma, even though ITO has high transmittance and electrical conductivity. Zinc oxide without aforementioned problems is also incapable of being applied to various photoelectric fields because of low electrical conductivity.

To improve electrical conductivity, zinc oxide is doped with an impurity, such as boron (B), aluminum (Al) or gallium (Ga), to form various TCO materials including boron-doped zinc oxide (BZO), aluminum-doped zinc oxide (AZO) or gallium-doped zinc oxide (GZO). By means of doping impurity to replace the lattice position of zinc, BZO, AZO or GZO has a desired electrical conductivity, i.e., a sheet resistivity less than 10 Ω/square, to be applied to various photoelectrical products.

According to Jun-ichi Nomoto et. al., J. Vac. Sci. Technol., A 29, (04), 1504, 2011, BZO thin film prepared by direct current magnetron sputtering, dc-MS sputtering, has intense variation in sheet resistivity, Hall mobility and carrier concentration; however, BZO thin film prepared by radio frequency magnetron sputtering, rf-MS sputtering, only has small variation in thereof.

Furthermore, since a raw material used in manufacturing BZO sputtering target comprises boron trioxide easily vaporized with increasing temperature, both boron content in a BZO sputtering target and boron content in a BZO thin film can hardly be controlled during a deposition process.

Based on these problems stated above, BZO thin film is deposited only by rf-MS sputtering with slower sputtering rate, rather than dc-MS sputtering to provide composition uniformity. No research has been reported presently that a BZO sputtering target can be sputtered by easy-controlled DC sputtering with high sputtering rate to form a BZO thin film applicable for a transparent conducting electrode of photoelectric products.

To overcome the shortcomings, the present invention provides a boron-doped zinc oxide sputtering target to mitigate or obviate the aforementioned problems.

### SUMMARY OF THE INVENTION

The primary objective of the present invention is to provide a boron-doped zinc oxide sputtering target, which can be sputtered by easy-controlled DC sputtering to form a boron-doped zinc oxide thin film with stable film quality and high production yield.

To achieve the aforementioned objective, the present invention provides a boron-doped zinc oxide sputtering target (BZO sputtering target), which has an amount of B/(B+Zn) (an amount of boron relative to a total amount of boron and zinc) ranging from 1.15 atomic % to 6.74 atomic %, wherein the boron-doped zinc oxide sputtering target is composed of a matrix phase and a second phase; and a percentage of an area of the second phase relative to a total area of the matrix phase and the second phase ranges from 2% to 25%.

As the area of the second phase is controlled within a suitable range, the BZO sputtering target is applicable for being sputtered by DC sputtering, thereby forming a BZO thin film with stable film quality.

Preferably, the percentage of the area of the second phase relative to the total area of the matrix phase and the second phase ranges from 5.5% to 16%.

Preferably, the matrix phase of the BZO sputtering target comprises a composition of zinc oxide (ZnO).

Preferably, the second phase of the BZO sputtering target comprises a composition of Zn_{(3+y)}B₍₂₋ₓ₎O₆, wherein x ranges from 0 to 0.5, and y ranges from 0 to 1.5. For example, the compositions of the second phase may be Zn_{3.6}B_{1.6}O₆, Zn_{4.1}B_{1.9}O₆ or Zn_{4.4}B_{1.9}O₆.

More preferably, the compositions of the second phase are Zn_{(3+y)}B₍₂₋ₓ₎O₆, wherein y=3/2x, x ranges from 0 to 0.5, and y ranges from 0 to 0.75.

Preferably, the BZO sputtering target further contains at least one dopant, which is selected from a group consisting of: aluminum (Al), gallium (Ga), indium (In), germanium (Ge), silicon (Si) and tin (Sn). Preferably, a total amount of the at least one dopant ranges from 0.25 atomic % to 0.5 atomic % relative to a total amount of boron and zinc in the BZO sputtering target.

Preferably, the BZO sputtering target has an absolute density more than 5.2 g/cm³.

To achieve the aforementioned objective, the present invention also provides a method of forming a boron-doped zinc oxide thin film, comprising the steps of: providing a BZO sputtering target as described above; and forming the BZO thin film on a substrate by DC sputtering.

Preferably, the DC sputtering is performed at a temperature ranging from 25° C. to 350° C., under a working pressure ranging from 1.7 mTorr to 9 mTorr and under a direct current power density ranging from 0.55 W/cm² to 7 W/cm².

To achieve the aforementioned objective, the present invention further provides a BZO thin film having an amount of B/(B+Zn) ranging from 1 atomic % to 6 atomic %, a resistivity ranging from 1×10⁻³ Ω-cm to 9×10⁻³ Ω-cm, and an average light transmittance ranging from 80% to 93% within a wavelength from 400 nanometers to 1100 nanometers.

Preferably, the BZO thin film has a resistivity ranging from 1×10⁻³ Ω-cm to 7×10⁻³ Ω-cm and an average light transmittance ranging from 89% to 92% within a wavelength from 400 nanometers to 1100 nanometers.

The BZO thin film can be prepared by various sputtering processes, for example, but not limited to, DC sputtering, dc-MS sputtering, pulsed DC sputtering, radio frequency sputtering or rf-MS sputtering.

Preferably, the BZO thin film is deposited by DC sputtering with any one of the aforementioned BZO sputtering targets. Preferably, the BZO thin film is prepared by the aforementioned method.

In summary, a BZO sputtering target having a second phase only 2% to 25% in area is obtained. By controlling the area of the second phase, the BZO sputtering target in accordance with the present invention can be sputtered by easy-controlled DC sputtering with high sputtering rate, and thereby improving the film quality and production yield of the BZO thin film.

Other objectives, advantages and novel features of the invention will become more apparent from the following detailed description when taken in conjunction with the accompanying drawings.

### BRIEF DESCRIPTION OF THE DRAWINGS

FIG. 1A is an optical microscope image of the BZO sputtering target of Example 1 in accordance with the present invention;

FIG. 1B is a scanning electron microscope image of the BZO sputtering target of Example 1 in accordance with the present invention;

FIG. 1C is a backscatter electron microscope image of the BZO sputtering target of Example 1 in accordance with the present invention;

FIG. 1D is an image analyzed with Image-Pro Plus 6.3 software of the BZO sputtering target of Example 1 in accordance with the present invention;

FIG. 2A is an optical microscope image of the BZO sputtering target of Example 2 in accordance with the present invention;

FIG. 2B is a scanning electron microscope image of the BZO sputtering target of Example 2 in accordance with the present invention;

FIG. 2C is a backscatter electron microscope image of the BZO sputtering target of Example 2 in accordance with the present invention;

FIG. 2D is an image analyzed with Image-Pro Plus 6.3 software of the BZO sputtering target of Example 2 in accordance with the present invention;

FIG. 3A is an optical microscope image of the BZO sputtering target of Example 3 in accordance with the present invention;

FIG. 3B is a scanning electron microscope image of the BZO sputtering target of Example 3 in accordance with the present invention;

FIG. 3C is a backscatter electron microscope image of the BZO sputtering target of Example 3 in accordance with the present invention;

FIG. 3D is an image analyzed with Image-Pro Plus 6.3 software of the BZO sputtering target of Example 3 in accordance with the present invention;

FIG. 4 is a graph of resistivity and average transmittance versus power density of the BZO thin films, which are deposited by DC sputtering with the BZO sputtering targets of Examples 1 to 3 in accordance with the present invention;

FIGS. 5A and 5B are graphs of average transmittance versus wavelength of an aluminum-doped zinc oxide (AZO) thin film (Comparative Example) and BZO thin films, wherein the BZO thin films are deposited by DC sputtering with the BZO sputtering targets of Examples 1 to 3 in accordance with the present invention.

### DETAILED DESCRIPTION OF THE PREFERRED EMBODIMENTS

Hereinafter, one skilled in the arts can easily realize the advantages and effects of a boron-doped zinc oxide sputtering target and its application in accordance with the present invention from the following examples. The descriptions proposed herein are just preferable embodiments for the purpose of illustrations only, not intended to limit the scope of the invention. Various modifications and variations could be made in order to practice or apply the present invention without departing from the spirit and scope of the invention.

### Examples 1 to 3

### BZO Sputtering Targets and their Applications

1. Method of Manufacturing a BZO Sputtering Target

The method of manufacturing BZO sputtering targets of Examples 1 to 3 were implemented as described below.

First, B₂O₃ powder and ZnO powder were provided. The B₂O₃ powder, ZnO powder, and an anionic dispersant were mixed with water to obtain a slurry. The amounts of B₂O₃ powder and ZnO powder implemented in Examples 1 to 3 were respectively listed on Table 1, the individual amounts of B₂O₃ powder and ZnO powder listed herein were calculated based on a total amount of the B₂O₃ powder and ZnO powder.

TABLE 1
the amounts of B₂O₃ powder and ZnO powder used for
manufacturing the BZO sputtering targets in Examples 1 to 3

| | Example 1 | Example 2 | Example 3 |
|---|---|---|---|
| ZnO powder | 99.2 wt % | 99 wt % | 98 wt % |
| B₂O₃ powder | 0.8 wt % | 1 wt % | 2 wt % |

Subsequently, the obtained slurry was mixed with a water-soluble binder, and then subjected to atomizer to form a mixed granular powder with a diameter of 60 nanometers.

After that, the mixed granular powder was filled into a graphite mold, and then subjected to cold pressing and cold isostatic pressing to preform a green compact.

Finally, the graphite mold with the preformed green compact was put into a furnace and sintered at 800° C. to 130° C. for 5 hours to 20 hours to obtain a BZO sputtering target of the present invention.

The microstructures of the obtained BZO sputtering targets in Examples 1 to 3 were observed by optical microscopy (OM), scanning electronic microscopy (SEM) and back scattered electron microscopy (BSE microscopy).

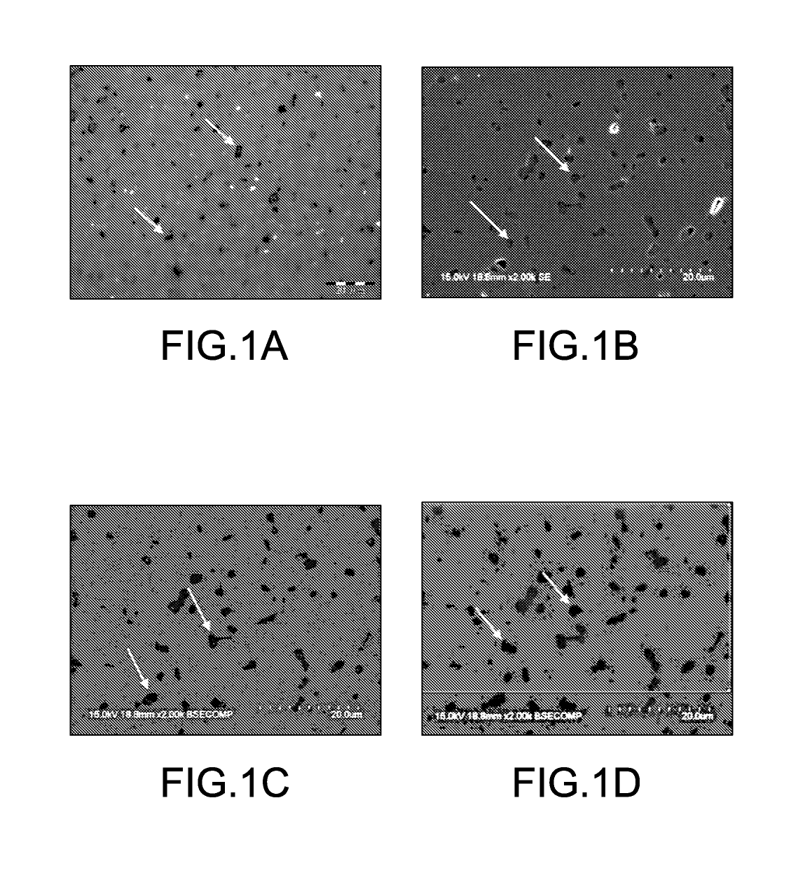

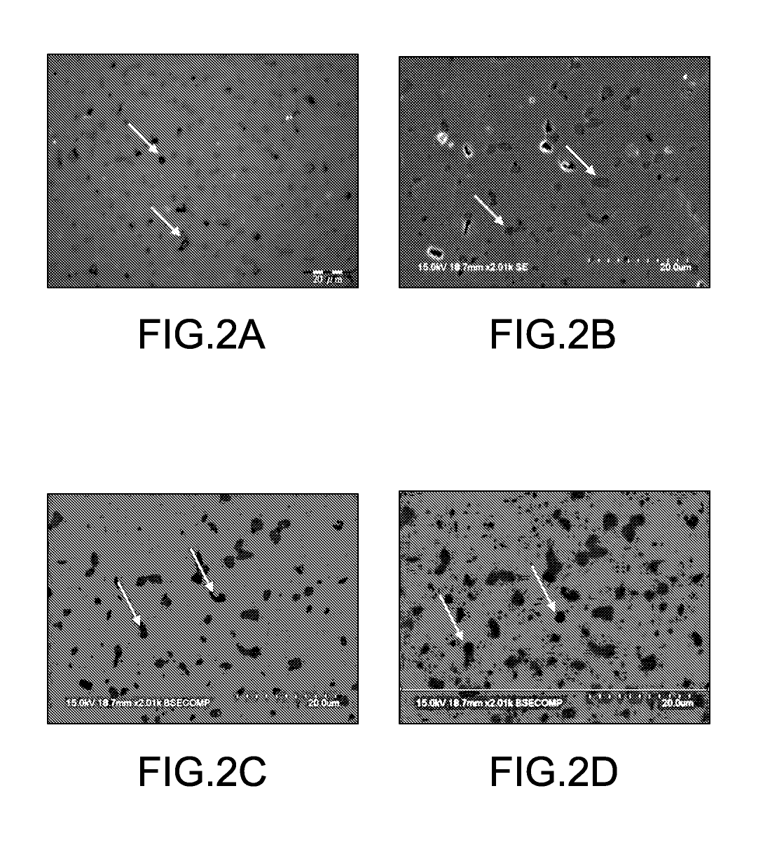

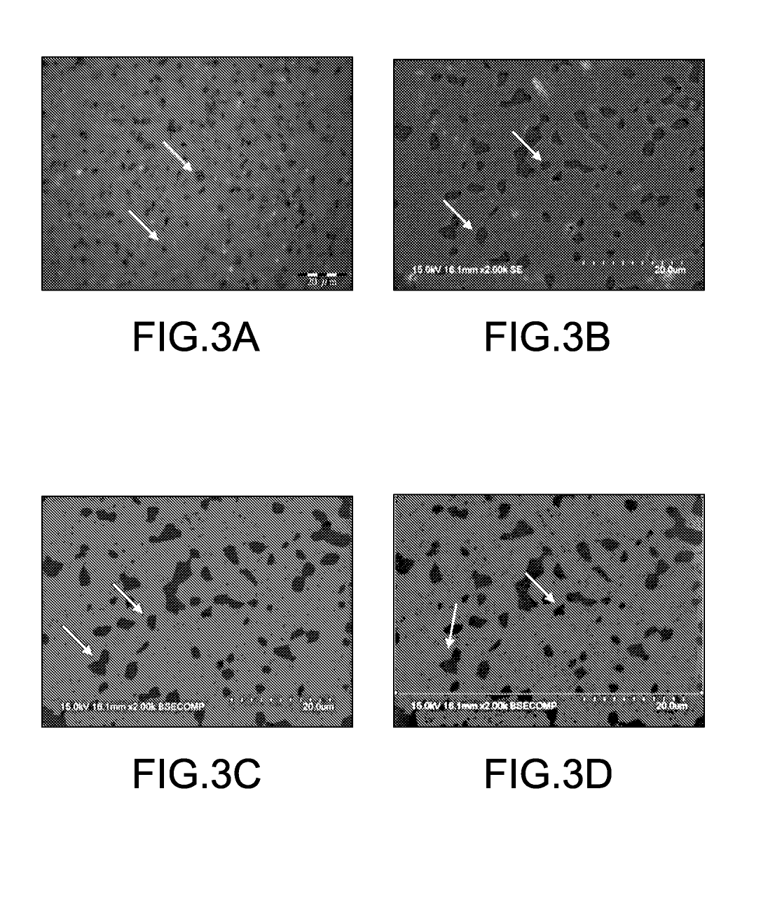

As shown in FIGS. 1A to 1C, 2A to 2C and 3A to 3C, the second phases of the BZO sputtering targets were marked with arrows. The compositions of the second phases in the BZO sputtering targets were determined by electron probe X-ray micro analyzer (EMPA), and the results were listed on the following Table 2.

In addition, a percentage of an area of the second phase relative to a total area of the BZO sputtering target was further analyzed with an Image-Pro Plus 6.3 software. Before analyzing the microstructure of the BZO sputtering target, SEM image with color differences were pictured. Depending on the color differences in SEM images, the contrast and brightness were further adjusted to enhance the differences between the second phases and surrounding ZnO matrix phases. Accordingly, the distributions of the second phases in the processed SEM images were successfully identified by Image-Pro Plus 6.3 software by calculating a percentage of an area of the identified second phase in the processed SEM image relative to an overall area of the processed SEM image. Hence, a percentage of an area of the second phase relative to a total area of the second phase and the matrix phase was identified.

As shown in FIGS. 1D, 2D and 3D, the second phases of the BZO sputtering targets in processed SEM images were marked with arrows. The components of the matrix phases and second phases, area percentages of the second phases relative to the overall processed SEM images, and absolute densities of the BZO sputtering targets in Examples 1 to 3 were also listed on the following Table 2.

TABLE 2
the components of the matrix phases and second phases, area
percentages of the second phases, and absolute densities of the
BZO sputtering targets in Examples 1 to 3

| | Example 1 | Example 2 | Example 3 |
|---|---|---|---|
| Component of | ZnO | ZnO | ZnO |
| matrix phase | | | |
| Component of | Zn_{3.6}B_{1.6}O₆ | Zn_{4.1}B_{1.9}O₆ | Zn_{4.4}B_{1.9}O₆ |
| second phase | | | |
| Area percentage of | 6.5 ± 1% | 10 ± 1% | 15 ± 1% |
| second phase | | | |
| Absolute density | 5.46 g/cm³ | 5.40 g/cm³ | 5.29 g/cm³ |

2. Depositing a BZO Thin Film by DC Sputtering

The BZO sputtering targets of Examples 1 to 3 were sputtered by DC sputtering at 170° C. and under a working pressure from 3 millitorrs (mtorr) to 5 mtorr to deposit 1000 nm-thick BZO thin films on glass substrates respectively. The power densities of DC sputtering implemented to sputter respective BZO thin films were listed on the following Table 3. Besides, results of composition, resistivity and transmittance of deposited BZO thin film deposited by respective BZO sputtering targets were also listed on the following Table 3. Here, the compositions of BZO thin films were represented by the relative amount of B/(B+Zn).

TABLE 3
the compositions, resistivities and average transmittances of the
deposited BZO thin films, which were formed by DC sputtering the BZO
sputtering targets of Examples 1 to 3 under different power densities

| BZO | Power | | | Average |
|---|---|---|---|---|
| sputtering | density | Composition of | Resistivity | transmittance |
| target | (W/cm²) | BZO thin film | (Ω-cm) | (%) |
| Example 1 | 2.2 | B/(B + Zn) = | 1.8 × 10⁻³ | 91.6 |
| | | 1.5~2.5 atomic % | | |
| Example 2 | 1.1 | B/(B + Zn) = | 2.93 × 10⁻³ | 89.9 |
| Example 2 | 2.2 | 3.7~4.1 atomic % | 2.31 × 10⁻³ | 89.5 |
| Example 2 | 3.8 | | 2.48 × 10⁻³ | 89.7 |
| Example 3 | 1.1 | B/(B + Zn) = | 6.88 × 10⁻³ | 90.5 |
| Example 3 | 1.6 | 4.1~5 atomic % | 6.83 × 10⁻³ | 90.3 |
| Example 3 | 2.2 | | 6.61 × 10⁻³ | 90.2 |

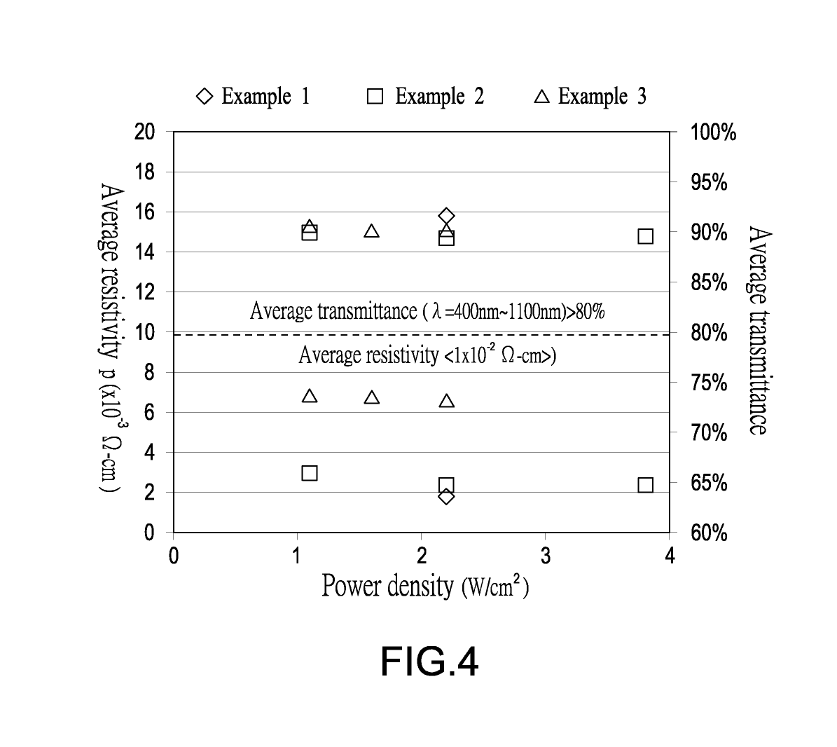

As shown in Table 3, a BZO thin film having an amount of B/(B+Zn) from 1.5 atomic % to 2.5 atomic % was produced by sputtering the BZO sputtering target of Example 1 under a DC power density of 2.2 W/cm². As shown in FIG. 4, the produced BZO thin film had a resistivity of 1.8×10⁻³ Ω-cm and an average transmittance about 91.6% within a wavelength from 400 nanometers to 1100 nanometers.

By means of sputtering the BZO sputtering target of Example 2, three BZO thin films having an amount of B/(B+Zn) from 3.7 atomic % to 4.1 atomic % were deposited. As shown in FIG. 4, the produced BZO thin films respectively had resistivities of 2.93×10⁻³ Ω-cm, 2.31×10⁻³ Ω-cm and 2.48×10⁻³ Ω-cm and average transmittances about 89.9%, 89.5% and 89.7% within a wavelength from 400 nanometers to 1100 nanometers when the BZO sputtering targets were respectively sputtered under DC power densities of 1.1 W/cm², 2.2 W/cm² and 3.8 W/cm².

By means of sputtering the BZO sputtering target of Example 3, three BZO thin films having an amount of B/(B+Zn) from 4.1 atomic % to 5.0 atomic % were deposited. As shown in FIG. 4, the produced BZO thin films respectively had resistivities of 6.88×10⁻³ Ω-cm, 6.83×10⁻³ Ω-cm and 6.61×10⁻³ Ω-cm and average transmittances about 90.5%, 90.3% and 90.2% within a wavelength from 400 nanometers to 1100 nanometers when the BZO sputtering targets were sputtered under DC power densities of 1.1 W/cm², 1.6 W/cm² and 2.2 W/cm².

### Comparative Example

### AZO Sputtering Target and its Application

An aluminum-doped zinc oxide (AZO) sputtering target was provided as a Comparative Example. Based on the total amount of the oxides comprised in AZO sputtering target, an amount of zinc oxide was 98 wt % and an amount of aluminum trioxide was 2 wt %.

Then, the AZO sputtering target was sputtered by DC sputtering at 170° C., under a working pressure of 3 mtorr and a power density of 2.2 W/cm² to deposit a 1000 nm-thick AZO thin film on a glass substrate.

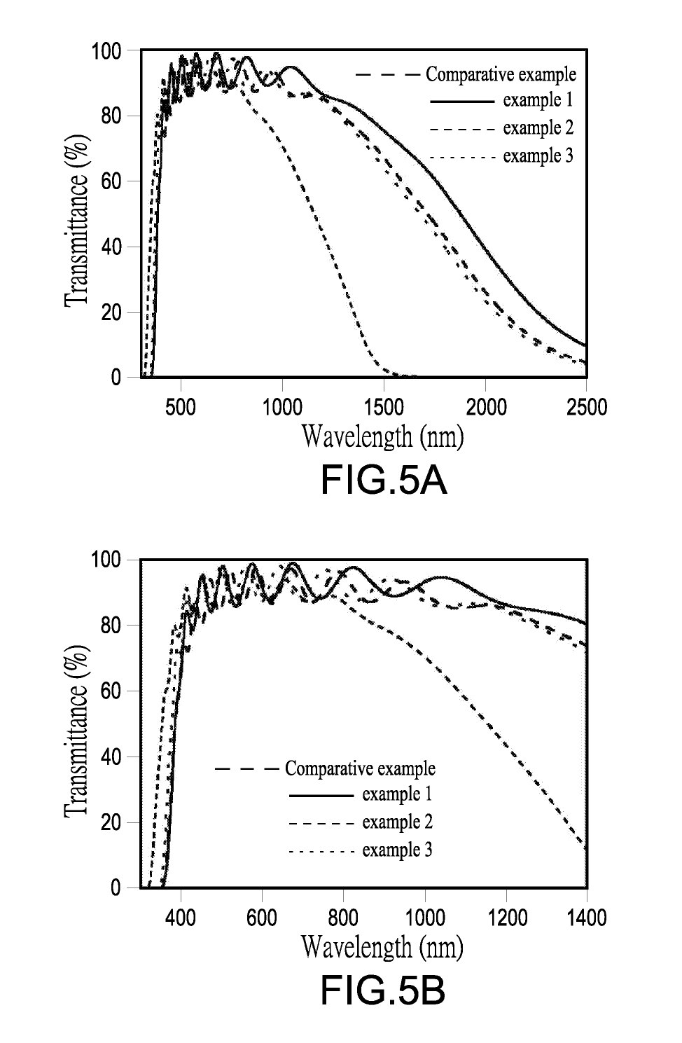

As shown in FIGS. 5A and 5B, the BZO thin films deposited by sputtering the BZO sputtering targets of Examples 1 to 3 do have a transmittance equivalent to that of AZO thin film within a wavelength from 400 nanometers to 700 nanometers, and have a transmittance higher than that of AZO thin film within a wavelength over 700 nm.

The results demonstrates that the BZO sputtering target in accordance with the present invention is applicable for being sputtered by fast DC sputtering to successfully prepare a conductive BZO thin film having a transmittance above 80% within a wavelength from 400 nanometers to 1100 nanometers and a resistivity less than 10⁻² Ω-cm.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A boron-doped zinc oxide sputtering target, which has an amount of B/(B+Zn) ranging from 1.15 atomic % to 6.74 atomic %, wherein the boron-doped zinc oxide sputtering target is composed of a matrix phase and a second phase; and a percentage of an area of the second phase relative to a total area of the matrix phase and the second phase ranges from 2% to 25%.

2. The boron-doped zinc oxide sputtering target as claimed in claim 1, wherein the percentage of the area of the second phase relative to the total area of the matrix phase and the second phase ranges from 5.5% to 16%.

3. The boron-doped zinc oxide sputtering target as claimed in claim 1, wherein the second phase comprises a composition of Zn_{(3+y)}B₍₂₋ₓ₎O₆, x ranges from 0 to 0.5, and y ranges from 0 to 1.5.

4. The boron-doped zinc oxide sputtering target as claimed in claim 3, wherein y=3/2x.

5. The boron-doped zinc oxide sputtering target as claimed in claim 1, wherein the matrix phase comprises a composition of zinc oxide (ZnO).

6. The boron-doped zinc oxide sputtering target as claimed in claim 1, wherein the boron-doped zinc oxide sputtering target further contains at least one dopant selected from a group consisting of aluminum, gallium, indium, germanium, silicon and tin.

7. The boron-doped zinc oxide sputtering target as claimed in claim 6, wherein a total amount of the at least one dopant ranges from 0.25 atomic % to 0.5 atomic % relative to a total amount of boron and zinc in the boron-doped zinc oxide sputtering target.

8. The boron-doped zinc oxide sputtering target as claimed in claim 1, wherein the boron-doped zinc oxide sputtering target has an absolute density more than 5.2 g/cm³.

9. The boron-doped zinc oxide sputtering target as claimed in claim 3, wherein the matrix phase comprises a composition of zinc oxide (ZnO).

10. The boron-doped zinc oxide sputtering target as claimed in claim 9, wherein the boron-doped zinc oxide sputtering target has an absolute density more than 5.2 g/cm³.

11. The boron-doped zinc oxide sputtering target as claimed in claim 10, wherein the percentage of the area of the second phase relative to the total area of the matrix phase and the second phase ranges from 5.5% to 16%.

12. The boron-doped zinc oxide sputtering target as claimed in claim 11, wherein the boron-doped zinc oxide sputtering target further contains at least one dopant selected from a group consisting of aluminum, gallium, indium, germanium, silicon and tin.

13. The boron-doped zinc oxide sputtering target as claimed in claim 12, wherein a total amount of the at least one dopant ranges from 0.25 atomic % to 0.5 atomic % relative to a total amount of boron and zinc in the boron-doped zinc oxide sputtering target.

14. The boron-doped zinc oxide sputtering target as claimed in claim 13, wherein y=3/2x.
